(19) United States
(12) Patent Application Publication
(10) Pub. No.: US 2012/0037919 A1
(43) Pub. Date: Feb. 16, 2012

(54) NANOPORE ELECTRICAL SENSOR

(75) Inventors: Ming-sheng Xu, Zhejiang (CN); Hongzheng Chen, Zhenjiang (CN); Minmin Shi, Zhejiang (CN); Gang Wu, Zhejiang (CN); Mang Wang, Zhejiang (CN)

(73) Assignee: Zhejian University, Zhejiang (CN)

(21) Appl. No.: 13/266,540

(22) PCT Filed: Sep. 14, 2010
(86) PCT No.: PCT/CN2010/076862

§ 371 Date: Oct. 27, 2011

(30) Foreign Application Priority Data
Oct. 22, 2009 (CN) 200910154046.8

(51) Int. Cl. H01L 29/66; H01L 29/16; H01L 29/20

(52) U.S. Cl. 257/76; 257/414; 257/E29.166; 257/E29.082; 257/E29.089

(57) ABSTRACT

A nanopore electrical sensor is provided. The sensor has layered structure, including a substrate (1), the first insulating layer (2), a symmetrical electrode (3) and the second insulating layer (5) from bottom to top in turn. A nanopore (6) is provided in the center of the substrate (1), the first insulating layer (2), the symmetrical electrode (3) and the second insulating layer (5). The thickness of the symmetrical electrode can be controlled between 0.3 nm and 0.7 nm so as to meet the resolution requirements for detecting a single base in a single-stranded DNA. Thus the sensor is suitable for gene sequencing. The present invention overcomes current technical insufficiency to integrate a nanoelectrode with a nanopore and the method to prepare the nanoelectrode is simple.

### FIELD OF THE INVENTION

The present invention relates to a type of sensor. In particular, a type of nanopore electrical sensor is discovered.

### BACKGROUND OF THE INVENTION

Nanopore can be used to detect and characterize biomolecules such as DNA, RNA and peptide at the single molecule level. Potential nanopore-based single molecular gene sequencing technology need neither fluorescent marker nor polymerase chain reaction (PCR), but directly and rapidly read base sequence in DNA strand. Such sequencing technology is expected to hugely reduce sequencing cost and achieve personalized medicine (see M. Zwolak, M. Di Ventra, Rev. Mod. Phys. 2008, 80, 141-165; D. Branton, et al. Nature Biotechnol. 2008, 26, 1146-1153). Nanopore-based single molecular gene sequencing technology enables DNA bases to pass through a pore, potentially one base at a time, under the effect of electrophoresis, and meanwhile the order in which nucleotides occur on a strand of DNA can be determined on the basis of optical or electrical signal difference recorded when DNA base passes through the nanopore. There are mainly three manners to readout DNA sequences based on nanopore technique, including strand-sequencing using ionic current blockage, strand-sequencing using transverse electron currents, and nanopore sequencing using synthetic DNA and optical readout. Currently, nanopore is generally made with depth over 10 nm, which is greatly larger than 0.3-0.7 nm, the distance between two neighboring bases in single-stranded DNA. In other words, 15 bases pass through the nanopore simultaneously, and thus it hardly meet single-base resolution requirement for gene sequencing. Consequently, in order to reach single-base resolution, a functional element is required to be able to detect a base at a time in a single-stranded DNA. In addition, ion blockage current through a nanopore is usually at pA level and is with low signal-to-noise ratio.

In 2005, Di Ventra et al. at University of California-San Diego reported through theoretical calculation (see M. Di Ventra, et al. Nano Lett. 2005, 5, 421-424.) that it is possible to sequence DNA by measuring the transverse tunneling electron current of DNA base as DNA strand passes through the nanopore. In order to achieve that, the nanopore system shall be integrated with nanoelectrodes, which can record the current values perpendicular to DNA strand as the DNA passes through the nanopore. Although current techniques making a nanopore is relatively mature (see J. Li, et al. Nature 2001, 412, 166-169; A. J. Storm, et al. Nature Mater. 2003, 2, 537-540; M. J. Kim, et al. Adv. Mater. 2006, 18, 3149-3153; B. M. Venkatesan, et al. Adv. Mater. 2009, 21, 2771-2776), there is few reports of integration of nanoelectrodes with single-base resolution into a nanopore system. Because the four kinds of DNA bases vary in structure and chemical properties, each one may possess specific electronic characteristics, which can be used to electronically sequence DNA. In 2007, Mingsheng Xu et al. experimentally demonstrated for the first time that the four DNA bases have base-specific electronic signatures (see M. S. Xu, et al. Small 2007, 3, 1539-1543.). Therefore, a rapid and cost-effective electronic DNA sequencing is expected to be achieved by measuring the electronic characteristics of DNA bases as a DNA strand passing through a nanopore with properly integrated electrodes.

### SUMMARY OF THE INVENTION

It is thus the object of the present invention to overcome current technical insufficiency to create a nanopore electrical sensor.

The following presents a simplified summary of the invention in order to provide a basic understanding of some aspects of the invention. This summary is not an extensive overview of the invention. It is intended neither to identify key or critical elements of the invention nor delineate the scope of the invention. Rather, its primary purpose is merely to present one or more concepts of the invention in a simplified form as a prelude to the more detailed description that is present later.

This object is achieved by means of the following technical proposals: a nanopore electrical sensor comprises a substrate, a first insulating layer, a symmetrical electrode array and a second insulating layer stacked from bottom to top with a nanopore provided in the center of each layer. The symmetrical electrode array is sandwiched between the first and the second insulating layers. In order to avoid error of signal sent by the electrode, the second insulating layer may cover the symmetrical electrode array, or cover both the symmetrical electrode array and the first insulating layer.

In a preferred embodiment of the invention, both upper surface of the first insulating layer and edge of each electrode in the symmetrical electrode array are provided to connect with an electrical contact layer.

In a preferred embodiment of the invention, said symmetrical electrode array consists of 1-30 paired electrodes. And the preferred number of pairs is 1 to 10. The electrodes can be different shapes such as S-shaped and radial-liked structures, and surround the nanopore. The electrodes in the array are separated from each other. The thickness of a nanoelectrode is typically 0.3-3.5 nm, but the optimal thickness is 0.3⁻¹ nm.

In a preferred embodiment of the invention, said symmetrical electrode array is made of a two-dimensional layered conductive material including graphite, reduced graphene oxide, partially hydrogenated graphene, BNC, MoS₂, NbSe₂ or Bi₂Sr₂CaCu₂Oₓ.

In a preferred embodiment of the invention, said layered conductive material is the graphite, specifically the graphite films are with 1-10 graphene layers, corresponding to the thickness of 0.3-3.5 nm, but more preferred ones are 1-3 layers of graphene.

In another preferred embodiment of the invention, said layered conductive material is the reduced graphene oxide, specifically the conductive reduced graphene oxide membrane obtained by carrying out reduction reaction of graphene oxide film. The preferred layers of reduced graphene oxide membrane are 1-10 with thickness of 0.3-3.5 nm, but more preferred number of layers is 1-3.

In another preferred embodiment of the invention, said layered conductive material is the partially hydrogenated graphene, specifically the hydrogenated graphene membrane obtained after the graphene membrane reacts with hydrogen and part of sp² bonding of the graphene are converted to C—H sp³ bonding. The preferred layers of partially hydrogenated graphene membrane are 1-10 with thickness of 0.3-3.5 nm, but more preferred ones are 1-3.

In another preferred embodiment of the invention, said layered conductive material is the BNC, specifically the layered conductive membrane (incl. boron, nitrogen and carbon) from hybridized boron nitride and graphene. The electrical properties of BNC is between the conductive graphene and insulating boron nitride. However, it is controllable by changing the content of boron, nitrogen and carbon (see Lijie C i, et al., “Atomic layers of hybridized boron nitride and graphene domains”, Nature Materials 9 (2010) 430-435). The preferred number of layers of BNC film is 1-10, corresponding to thickness of 0.3-3.5 nm, but more preferred ones are 1-3.

In another preferred embodiment of the invention, said layered conductive material is the MoS₂, specifically the MoS₂ membrane with thickness of 0.3-3.5 nm. The preferred layers of MoS₂ membrane are 1-10 but more preferred ones are 1-3.

In another preferred embodiment of the invention, said layered conductive material is the NbSe₂, specifically NbSe₂ films with thickness of 0.3-3.5 nm. The preferred number of layers of NbSe₂ films is 1-10 but more preferred is 1-3.

In a preferred embodiment of the invention, said layered conductive material is the Bi₂Sr₂CaCu₂Oₓ, specifically the Bi₂Sr₂CaCu₂Oₓ film with thickness of 0.3-3.5 nm. The preferred number of layers of Bi₂Sr₂CaCu₂Oₓ film is 1-10 but more preferred one is 1-3.

In a preferred embodiment of the invention, a material of said substrate is made of a semiconductive material including one or mixture of Si, GaN, Ge or GaAs, and insulating material including one or mixture of SIC, Al₂O₃, SiNₓ, SiO₂, HfO₂, polyvinyl alcohol (PVA), poly(4-vinylphenol), divinyltetramethyldisiloxane-bis-benzocyclobutene or poly(methyl methacrylate) (PMMA).

In a preferred embodiment of the invention, said first insulating layer and second insulating layer are SiO₂, Al₂O₃, HfO₂, BN, SiC, SiNₓ, PVA, poly(4-vinylphenol), divinyltetramethyldisiloxane-bis-benzocyclobutene, PMMA, or mixture of them. The substrate may be the same material as the first insulting layer.

In a preferred embodiment of the invention, said electrical contact layer is made of Au, Cr, Ti, Pd, Pt, Cu, Al, Ni, PEDOT:PEDOT or mixture of them. Since the thickness of said nanoelectrode pairs in the said symmetric electrode array is 0.3-3.5 nm, said electrical contact layer is adopted to improve electrical coupling between the nanoelectrodes of said symmetrical electrode array and external measuring instruments.

In a preferred embodiment of the invention, said symmetrical electrode array is sandwiched between the first insulating layer and the second insulating layer. The insulating layers can protect the electrodes and facilitate signal detection and record.

In a preferred embodiment of the invention, said nanopore is arranged at the intersection point of said symmetrical electrode array.

In a preferred embodiment of the invention, said nanopore is a round hole with diameter of 1-50 nm, preferred diameter 1-10 nm and optimal diameter 1-3 nm. Such hole helps to ensure the isotropy of the sensor. In another preferred embodiment of the invention, the nanopore may also be a polygon hole or an elliptical hole.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

The thickness of the symmetrical electrode can be controlled between 0.3 nm and 0.7 nm so as to meet resolution requirements for detecting a single base in a single-stranded DNA and thereby accomplish a rapid and cost-effective electronic DNA sequencing. The nanopore electrical sensor of the present invention overcomes the technical difficulties to integrate a nanoelectrode with a nanopore. And the fabrication of the nanoelectrodes is fairly simple. Moreover, because the electrodes are sandwiched two insulating layers, it is more robust and can prevent contamination and unnecessary environmental impact.

### BRIEF DESCRIPTION OF THE DRAWINGS

FIG. 1 shows a fabrication procedure of a nanopore electrical sensor in accordance with the invention, in which the electrode layer is transferred onto an insulating layer after the electrode layer was prepared on a substrate,

FIG. 2 shows optical image of a graphene film after being transferred onto SiO₂/Si substrate,

FIG. 3 shows Raman spectrum of a graphene after being transferred onto SiO₂/Si,

FIG. 4 shows fabrication procedure a nanopore electrical sensor in accordance with the invention, in which the graphene electrode layer is directly prepared on SiC insulating layer that serves as the substrate and first insulating layer of the nanopore electrical sensor,

FIG. 5 shows fabrication processes of a nanopore electrical sensor in accordance with the invention, in which the electrode layer is formed on the pre-patterned metal catalytic layer on a substrate,

FIG. 6 shows a diagram of a nanopore electrical sensor in accordance with the invention,

FIG. 7 shows cross-sectional view of a nanopore electrical sensor in accordance with the invention

The attached figures show substrate 1, first insulating layer 2, symmetrical and separated electrode array 3, electrical contact layer 4, second insulating layer 5, nanopore 6, electrode layer 7, and catalytic layer 8.

### DESCRIPTION OF THE PREFERRED EMBODIMENT

The disclosure will now be described in greater detail with reference to the following examples. The following examples are for illustrative purposes only and are not intended to limit the scope of the invention.

### Embodiment 1

synthesis of graphene on Cu film by chemical vapor deposition (CVD) method may include the following steps. Prepare 1000 nm Cu film on SiO₂ (300 nm)/Si (500 μm) substrate; load it into ultrahigh vacuum (5.0×10⁻⁹ ton); heat the Cu/SiO₂/Si at 950° C. for 30 min; form graphene on the Cu surface in C₂H₄ gas (˜10 Pa) environment for 10 min; and finally cool down the sample to room temperature quickly to obtain graphene film on the Cu film.

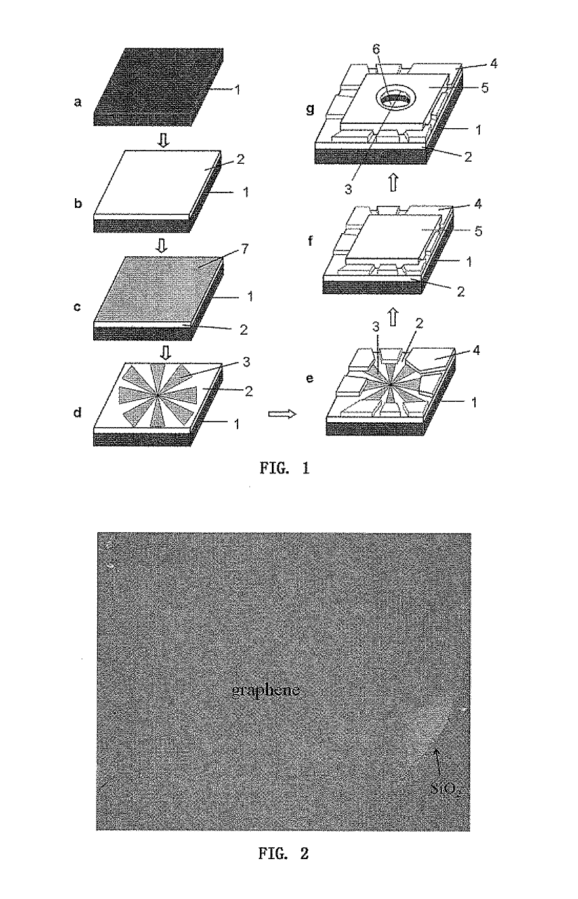

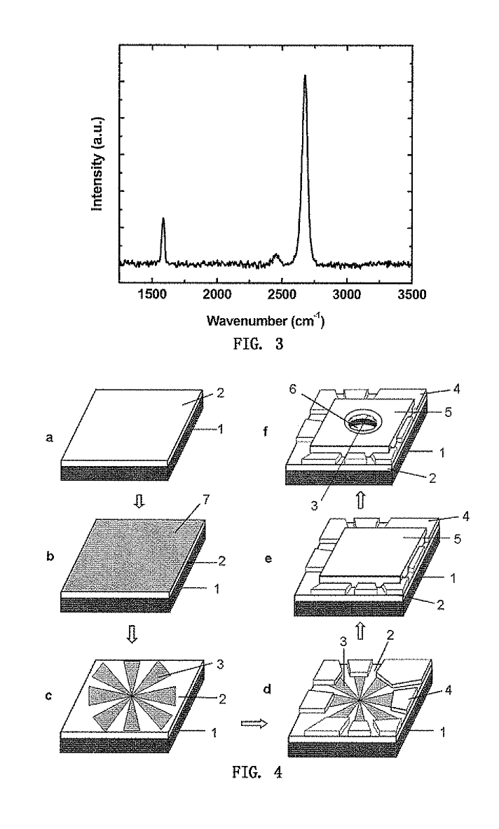

Referring to FIG. 1, FIG. 1 illustrates the process to prepare 100 nm SiO₂ as the first insulating layer 2 (FIG. 1b) on single crystal silicon substrate 1 with thickness of 500 μm (FIG. 1a).

Transfer the synthesized graphene film onto the SiO₂/Si (FIG. 1c): spin-coat 500 nm polymethylmethacrylate (PMMA) on the synthesized graphene surface; put the PMMA/graphene/Cu into ferric nitrate solution to etch Cu layer away so as to obtain PMMA/graphene membrane; transfer the PMMA/graphene membrane onto the SiO₂/Si that is used to fabricate nanopore electrical sensor; and finally remove the PMMA by acetone. Thus, the graphene layer 7 is transferred onto the SiO₂/Si (FIG. 1c).

FIG. 2 shows optical image of the graphene layer transferred onto SiO₂/Si. The characteristics of Raman spectra acquired from the transferred graphene layer suggest single-layer graphene.

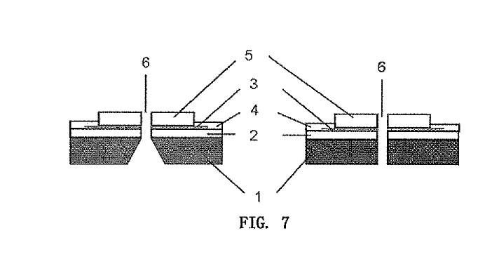

Formation of symmetrical electrode array 3 is carried out by patterning the graphene layer 7 (FIG. 1d) with photolithography, lift-off and oxygen plasma etching techniques. By considering the thickness of monolayer graphene (0.335 nm), an electrical contact layer 4 consisting of Cr (5 nm)/Au (50 nm) coupled to the symmetrical electrode array 3 is prepared (FIG. 1e) by using photolithography and lift-off techniques. After that, 70 nm Al₂O₃ and 100 nm Si₃N₄ acting as the second insulating layer 5 (FIG. 1f) is prepared by atomic layer deposition (ALD) and PECVD methods, respectively. Finally, a nanopore 6 with size of 1 nm is formed at the center of the layered structure (FIG. 1g, FIG. 6 and FIG. 7).

Results and analysis: layered conductive material such as graphene films, reduced graphene oxide, partially hydrogenated graphene, BNC, MoS₂, NbSe₂ or Bi₂Sr₂CaCu₂Oₓ can be used to make nanoelectrode. In this embodiment, graphene film is adopted for the nanoelectrode.

Different methods can be used to make graphene films as known in the art, including but not limited to, CVD method, surface segregation, mechanical exfoliation, and chemical reaction methods. For CVD method, catalytic metals such as Cu, Ni, Pt, Pd, Ir, Zn, Al, Fe, Mn, Ru, Re, Cr, and Co with thickness of 5 nm-2000 nm may need. In this embodiment, Cu is adopted for the metal catalytic layer.

Carbon-based materials as the carbon source for graphene synthesis by CVD method include but not limited to methane, ethane, ethylene, ethanol, acetylene, propane, propylene, butane, butadiene, pentane, pentene, cyclopentadiene, hexane, cyclohexane, and benzene. In this embodiment, ethylene is adopted to synthesize the graphene.

It is easy to synthesize large-scale single-layer graphene on Cu catalytic metal by CVD method and to transfer the graphene to an insulating layer as demonstrated in this embodiment.

Generally, insulating film material for preparing nanopore includes SiO₂, Al₂O₃, SiNx, BN, SiC, PVA, poly(4-vinylphenol), divinyltetramethyldisiloxane-bis-benzocyclobutene, PMMA, or mixture of them. In this embodiment, SiO₂ is adopted for the first insulating layer.

The substrate is generally made of Si, GaN, Ge, GaAs, SIC, Al₂O₃, SiNₓ, SiO₂, HfO₂, PVA, poly(4-vinylphenol), divinyltetramethyldisiloxane bis-benzocyclobutene, polymethyl methacrylate or mixture of them. In this embodiment, Si is adopted for the substrate.

The thickness of an electrode layer is 0.3-3.5 nm, and preferably, 0.3-1 nm. The number of pairs of a symmetrical electrode array is 1-30, and preferably 1-5 pairs. The electrode in a symmetrical electrode array is separated from each other. In this embodiment, the thickness of the graphene electrode layer 7 is 0.335 nm and the symmetrical electrode array 3 has 4-paired electrodes.

The fabrication of symmetrical electrode array may be carried out by using photolithography, electron beam lithography, laser photolithography, reactive ion-beam etching, oxygen plasma etching, helium ion-beam etching, or other techniques as in the art. In this embodiment, photolithography, lift-off, and oxygen plasma etching techniques are adopted to form graphene electrode array.

The electrical contact layer 4 coupled to the symmetrical electrode array 3 can be selected from Au, Cr, Ti, Pd, Pt, Cu, Al, Ni, PEDOT:PSS, or mixture of them. The preparation of an electrical contact layer 4 can be performed by the methods as known in the art, such as vacuum thermal evaporation, solution-based spin-coating, thermal oxidation, low pressure CVD, plasma enhanced chemical vapor deposition (PECVD), and ALD methods. The thickness of an electrical contact layer is 15-600 nm. In this embodiment, a stacked Cr (5 nm)/Au (50 nm) layer is used as the electrical contact layer 4, which is prepared by photolithography and lift-off techniques.

The second insulating layer 5 is made of one of SiO₂, Al₂O₃, HfO, BN, SiC, SiNg, PVA, poly(4-vinylphenol), divinyltetramethyldisiloxane bis-benzocyclobutene, PMMA, or mixture of them. The insulating layer 5 can be prepared by the methods as known in the art, including but not limited to vacuum thermal evaporation, solution-based spin-coating, thermal oxidation, low pressure CVD, PECVD, and ALD methods with typical thickness of 3 nm-3 μm. In this embodiment, ALD and PECVD methods are adopted to prepare 70 nm Al₂O₃ and 100 nm Si₃N₄, respectively, serving as the second compound insulating layer 5.

Nanopore 6 with a size or diameter of 1-50 nm can be of variable shapes, preferably round shape, prepared by a nanofabrication technology including but not limited to electron beam lithography, focused ion-beam etching, helium ion-beam lithography, and plasma etching methods. In this embodiment, the diameter of the prepared nanopore 6 is 1 nm.

### Embodiment 2

Referring to FIG. 4, load single crystal SiC{0001} substrate 1 with thickness of 500 μm into ultrahigh vacuum (1.0×10⁻¹° torr) for heat treatment (950° C.-1400° C.) to obtain the Si-terminated surface. The SiC substrate is also acted as the first insulating 2 (FIG. 4a). Such treatment leads to form epitaxial graphene layer as an electrode layer 7 (FIG. 4b). By using helium ion-beam etching technique, symmetrical electrode array 3 is patterned (FIG. 4c). Considering the thickness of graphene layer is 0.7 nm on the SiC, an electrical contact layer 4 consisting of Pd (50 nm) is prepared by photolithography and lift-off techniques (FIG. 4d). Then 100 nm Si₃N₄ serving as second insulating layer 5 (FIG. 4e) is prepared by low pressure CVD. Finally, a nanopore 6 with size of 3 nm (FIG. 4f, FIG. 6 and FIG. 7) is formed at the center of the radial-liked symmetrical electrode array 3.

Results and analysis: generally, insulating film material such as SiO₂, Al₂O₃, HfO₂, SiNₓ, BN, SiC, PVA, poly(4-vinylphenol), divinyltetramethyldisiloxane-bis-benzocyclobutene, PMMA, or mixture of them can be used to prepare the nanopore. In this embodiment, SiC is adopted for the first insulating layer.

The substrate 1 can be semiconductor or insulator, generally including Si, GaN, Ge, GaAs, SiC, Al₂O₃, SiNₓ, SiO₂, HfO₂, PVA, poly(4-vinylphenol), divinyltetramethyldisiloxane-bis-benzocyclobutene, polymethyl methacrylate, or mixture of them. In this embodiment, Si is adopted for the substrate 1.

Layered conductive material such as graphene films, reduced graphene oxide, partially hydrogenated graphene, BNC, MoS₂, NbSe₂ or Bi₂Sr₂CaCu₂Oₓ can be used to make nanoelectrode layer 7. In this embodiment, graphene layer is adopted for the nanoelectrode layer 7. As a result, in an embodiment, the substrate and the first insulating layer can be the same material.

In this embodiment, graphene electrode layer 7 is synthesized directly on insulated SiC by carbon segregation from the SiC. The SiC serves as the solid carbon source for formation of graphene electrode layer 7, the substrate 1 and the first insulating layer 2. Thus, there is no need to transfer the graphene layer.

The thickness of the prepared graphene electrode layer 7 in this embodiment is 0.7 nm and the number of pairs of symmetrical electrode array 3 is 4.

The symmetrical electrode array 3 may be patterned by means of photolithography, electron beam lithography, laser photolithography, reactive ion-beam etching, oxygen plasma etching, and helium ion-beam lithography. In this embodiment, electron beam lithography is adopted to prepare the radialized and centrally intersected graphene symmetrical electrode array.

The electrical contact layer 4 coupled to the symmetrical electrode array 3 is made of Au, Cr, Ti, Pd, Pt, Cu, Al, Ni, PSS:PEDOT, or mixture of them. The preparation of an electrical contact layer 4 can be done by the methods as known in the art, such as vacuum thermal evaporation, solution-based spin-coating, thermal oxidation, low pressure CVD, plasma enhanced chemical vapor deposition (PECVD), and ALD methods. The thickness of an electrical contact layer is 15-600 nm, and preferably 20-50 nm. In this embodiment, 50 nm Pd serves as the electrical contact layer 4, electrically coupled to the symmetrical graphene electrode array 3.

The materials used as the second insulating layer 5 may be SiO₂, Al₂O₃, BN, SiC, SiNₓ, PVA, poly(4-vinylphenol), divinyltetramethyldisiloxane bis-benzocyclobutene, PMMA, or mixture of them. The second insulating layer 5 with typical thickness of 3 nm-3 μm can be prepared by the methods as known in the art, including but not limited to vacuum thermal evaporation, solution-based spin-coating, thermal oxidation, low pressure CVD, PECVD, and ALD methods. In this embodiment, low pressure CVD method is used to prepare 100 nm Si₃N₄ film as the second insulating layer 5.

Nanopore 6 with a size or diameter of 1-50 nm can be of variable shapes, preferably round shape, prepared by a nanofabrication technology including but not limited to electron beam lithography, focused ion-beam etching, helium ion-beam lithography, and plasma etching methods. In this embodiment, the diameter of the prepared nanopore 6 is 3 nm.

### Embodiment 3

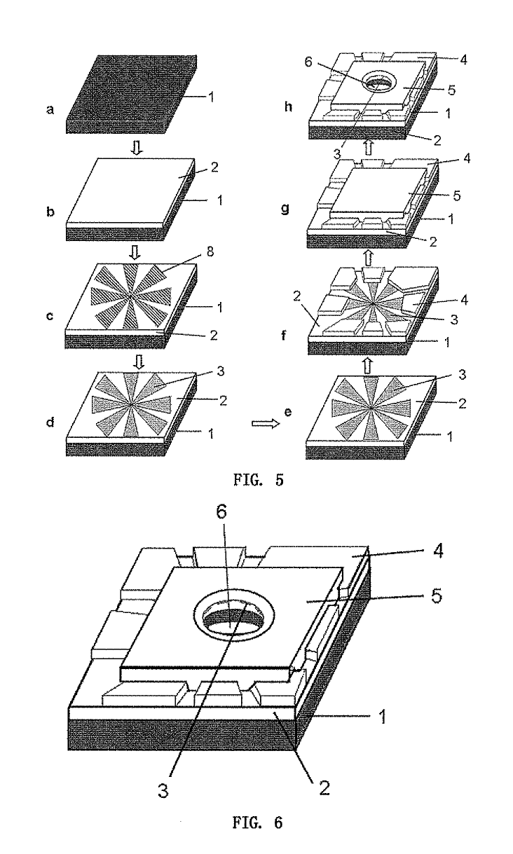

referring to FIG. 5, fabrication of nanopore electrical sensor may include the following steps: preparation of a combined layer of 100 nm SiO₂ and 30 nm Si₃N₄ as the first insulating layer 2 (FIG. 5b) on a 600-μm-thick single crystal Si substrate 1 (FIG. 5a); formation of symmetrical-electrode-array-liked pattern of 100 nm Ni metal catalytic layer 8 (FIG. 5c) on the surface of Si₃N₄ first insulating layer 2 by using electron beam lithography and thermal evaporation techniques. The Ni pattern is used to synthesize graphene on it. Preferably, the synthesis of graphene layer on the patterned Ni layer 8 is as follows. Load the Ni/Si₃N₄/SiO₂/Si into a ultrahigh vacuum (9×10⁻⁹ torr) chamber, and heat the structure at 950° C. for 30 min in CH₄ (FIG. 5d) to form graphene layer on the Ni film. After that, the Ni layer is removed by using 1M FeCl₃ solution, Consequently, the graphene layer with thickness of approx. 1.05 nm is automatically left on the Si₃N₄/SiO₂ first insulating layer 2 (FIG. 5e). In order to establish an effective electrical contact, 50 nm Pt film as an electrical contact layer 4 (FIG. 5f) is prepared to be electrically coupled to the graphene symmetrical electrode array 3. Then, a 150 nm Al₂O₃ layer as the second insulating layer 5 (FIG. 5g) is deposited by ALD method. Finally, nanopore 6 with size of 30 nm (FIG. 5h, FIG. 6 and FIG. 7) is prepared.

Results and analysis: The material for symmetrical electrode array can be made of graphene film, reduced graphene oxide, partially hydrogenated graphene, MoS₂, NbSe₂ or Bi₂Sr₂CaCu₂Oₓ. In this embodiment, graphene film is used for the symmetrical electrode array 3.

As for CVD method to synthesize graphene film, a metal catalytic layer 8 may include a material selected from the group consisting of Cu, Ni, Pt, Pd, Ir, Zn, Al, Fe, Mn, Ru, Re, Cr, Co with thickness of 15 nm-6000 μm. In this embodiment, 100 nm Ni is used as the catalytic layer 8, and the Ni catalytic layer is patterned into the same shape as the symmetrical electrode array.

Carbon-based materials as the carbon source for graphene synthesis by CVD method include but not limited to methane, ethane, ethylene, ethanol, acetylene, propane, propylene, butane, butadiene, pentane, pentene, cyclopentadiene, hexane, cyclohexane, and benzene. In this embodiment, methane is used as the carbon source for the formation of graphene layer.

Generally, material for the first insulating layer 2 include SiO₂, Al₂O₃, SiNx, HfO₂, BN, SiC, PVA, poly(4-vinylphenol), pivinyltetramethyldisiloxane-bis-benzocyclobutene, PMMA or mixture of them. In this embodiment, Si₃N₄/SiO₂ is adopted for the first insulating layer 2.

The substrate 1 of the insulating film material is generally made of Si, GaN, Ge, GaAs, SiC, Al₂O₃, SiO₂, HfO₂, PVA, poly(4-vinylphenol), divinyltetramethyldisiloxane bis-benzocyclobutene or PMMA. In this embodiment, Si is adopted for the substrate 1.

In this embodiment, the thickness of the graphene film for the symmetrical electrode array 3 is 1.05 nm and array 3 has 4-paired electrodes.

The electrical contact layer 4 electrically coupled to the symmetrical electrode array 3 can be a material selected from the group consisting of Au, Cr, Ti, Pd, Pt, Cu, Al, Ni, and PEDOT:PSS. The electrical contact layer 4 with typical thickness of 15-600 nm can be prepared by means of vacuum thermal evaporation, solution spin-coating, thermal oxidation, low pressure CVD, PECVD and ALD methods selected being that is required for the preparation. In this embodiment, a Pt (50 nm) layer is used as the electrical contact layer 4, which is prepared by photolithography and lift-off techniques.

Generally, the material served as the second insulating layer 5 can be the same material as the first insulating layer 2. In this embodiment, ALD method is adopted to prepare 150 nm Al₂O₃ as the second insulating layer 5.

In this embodiment, the diameter of the prepared nanopore 6 is 30 nm.

In this embodiment, a Ni metal catalytic layer is prepared on the first insulating layer. The Ni layer serves as a template to forming graphene symmetrical electrode array. Thus, the graphene layer synthesized on the Ni pattern is directly left on the first insulating layer to become the symmetrical electrode array after the Ni metal catalytic layer has been removed. In this way, there is no need to transfer graphene to other target substrate.

### Embodiment 4

using BNC layer as electrode layer. Preparation of BNC film by CVD method may be as follows. Load 30 μm Cu foil into ultrahigh vacuum chamber (5.0×10⁻⁸ torr); heat the Cu foil at 700° C. for 20 min under Ar/H₂ (˜20 vol % H₂) environment; increase the temperature to 950° C. and remain for 40 min. Afterwards, replace Ar/H₂ with a mixture of methane and ammonia to synthesize BNC film with thickness of 0.7 nm for 15 min. The synthesized BNC film is acted as electrode layer 7.

Referring to FIG. 1, a combined 100 nm SiO₂ and 50 nm SiNₓ serving as the first insulating layer 2 (FIG. 1b) is prepared on single crystal Si substrate 1 (FIG. 1a) with thickness of 500 μm.

Transfer the synthesized BNC film to the first insulating layer 2 as electrode layer 7 (FIG. 1c): spin-coat 500 nm PMMA on synthesized BNC layer; immerge the PMMA/BNC/Cu into 1M ferric nitrate solution to etch the Cu foil away so as to obtain PMMA/BNC membrane; then transfer the PMMA/BNC membrane onto SiNₓ/SiO₂/Si that is used to make nanopore electrical sensor; and finally use acetone to dissolve PMMA. In this way, the BNC membrane layer is transferred onto SiNₓ/SiO₂/Si to serve as the electrode layer 7 (FIG. 1c).

The BNC electrode layer 7 is patterned into BNC symmetrical electrode array 3 (FIG. 1d) by electron beam lithography method. Because the thickness of the BNC electrode layer 7 is approx. only 0.7 nm, in order to establish an effective electrical contact, Ti (10 nm)/Au (50 nm) layer is prepared as the electrical contact layer 4 (FIG. 1e) to be coupled to the symmetrical electrode array 3 by photolithography and lift-off techniques. And then 50 nm HfO₂ of the second insulating layer 5 is prepared (FIG. 1f) by ALD method. Finally a nanopore 6 with size of 1.6 nm (FIG. 1g, FIG. 6 and FIG. 7) is fabricated at the centrally intersected position of the symmetrical electrode array 3.

Results and analysis: The symmetrical electrode array 3 can be made of a 2-dimensional layered material selected from the groupog graphite, graphene layer, reduced graphene oxide, partially hydrogenated graphene, BNC, MoS₂, NbSe₂, and Bi₂Sr₂CaCu₂Oₓ. In this embodiment, BNC layer is adopted for the symmetrical electrode array 3.

To synthesize of BNC by CVD method, a metal catalytic layer may be selected from the group consisting of Cu, Ni, Pt, Pd, Ir, Zn, Al, Fe, Mn, Ru, Re, Cr, and Co. In this embodiment, 30 μm Cu foil is adopted for the catalytic material.

The carbon source for forming a BNC film includes but not limited to methane, ethane, ethylene, ethanol, acetylene, propane, propylene, butane, butadiene, pentane, pentene, cyclopentadiene, hexane, cyclohexane, and benzene. In this embodiment, methane is used as the carbon source and ammonia is used as the nitrogen source to synthesize BNC membrane. Other material containing nitrogen may be used such as nitrogen oxide. Meanwhile, the electrical conductivity of the BNC film can be tuned by adjusting the content of N and C in BNC.

In this embodiment, the thickness of the BNC symmetrical electrode array 3 is 0.7 nm and the number of pairs of the symmetrical electrode array 3 is 4.

Generally, material for the first insulating layer 2 include SiO₂, Al₂O₃, SiNx, HfO₂, BN, SiC, PVA, poly(4-vinylphenol), divinyltetramethyldisiloxane-bis-benzocyclobutene, or PMMA. The supporting material of the insulating film is generally made of Si, GaN, Ge, GaAs, SiC, Al₂O₃, SiNₓ, SiO₂, HfO₂, PVA, poly(4-vinylphenol), divinyltetramethyldisiloxane-bis-benzocyclobuteneor polymethyl methacrylate. In this embodiment, the prepared BNC membrane is transferred onto SiNₓ/SiO₂/Si.

The symmetrical electrode array 3 with a radiating structure can be prepared by means of photolithography, electron beam lithography, laser photolithography, reactive ion-beam etching, oxygen plasma etching, and Helium ion beam lithography. In this embodiment, electron beam lithography method is adopted to make radialized and centrally intersected BNC symmetrical electrode array 3.

The electrical contact layer 4 electrically coupled to the symmetrical electrode array 3 may be a material selected from the group consisting of Au, Cr, Ti, Pd, Pt, Cu, Al, Ni, and PEDOT:PSS, or mixture of them. The electrical contact layer 4 with typical thickness of 15-600 nm can be prepared by means of vacuum thermal evaporation, solution spin-coating, thermal oxidation, low pressure CVD, PECVD and ALD methods selected being that is required for the preparation. In this embodiment, a layer of Ti (10 nm)/Au (50 nm) is used as the electrical contact layer 4 being coupled to the symmetrical electrode array 3.

The second insulating layer 5 may be a material selected from the group consisting of SiO₂, Al₂O₃, BN, HfO₂, SiC, SiNₓ, PVA, poly(4-vinylphenol), divinyltetramethyldisiloxane-bis-benzocyclobutene, PMMA, or mixture of them. The insulating layer 5 with thickness of 3 nm-3 μm can be prepared by the methods as known in the art such as vacuum thermal evaporation, solution spin-coating, thermal oxidation, low pressure CVD, PECVD, and ALD methods. In this embodiment, ALD method is adopted to prepare 50 nm HfO₂ layer as the insulating layer 5.

Nanopore 6 with a size or diameter of 1-50 nm can be of variable shapes, preferably round shape, prepared by a nanofabrication technology including but not limited to electron beam lithography, focused ion-beam etching, helium ion-beam lithography, and plasma etching methods. In this embodiment, the diameter of the prepared nanopore 6 is 1.6 nm.

### Embodiment 5

synthesis of graphene film on Ni may include the following steps. Prepare 100 nm Ni film on highly oriented pyrolytic graphite (HOPG) substrate; load the HOPG/Ni into ultrahigh vacuum (5.0×10⁻⁸ torr) chamber; heat the HOPG/Ni at 650° C. for 17 h under H₂ (10 Pa); and then cool down the temperature to room temperature quickly. Thus, graphene film is synthesized on the Ni surface.

Referring to FIG. 1. FIG. 1 illustrates the processes to fabricate nanopore electrical sensor. A layer of 100 nm thick PVA is prepared on single crystal Si substrate (FIG. 1a) serving as the first insulating layer 2 (FIG. 1b).

Transfer the graphene film synthesized on HOPG/Ni onto the first insulating layer 2 as the electrode layer 7 (FIG. 1c) may comprise the following steps. Spin-coat 500 nm PMMA on synthesized graphene surface; etch the Ni away by immerging the HOPG/Ni/graphene/PMMA into ferric nitrate solution; and then transfer the graphene/PMMA onto Si/PVA surface; finally remove PMMA by acetone. In this way, the graphene layer is transferred onto the PVA surface to form the electrode layer 7 (FIG. 1c).

In particular, helium ion-beam etching technique is used to pattern symmetrical electrode array 3 (FIG. 1d).

Since the thickness of the graphene membrane nanoelectrode layer 7 is only 0.335 nm, photolithography and lift-off techniques are used to fabricate Ti (10 nm)/Au (50 nm) layer as the electrical contact layer 4 (FIG. 1e), electrically coupled to the symmetrical electrode array 3. After that, 100 nm SiNₓ film acting as the second insulating layer 5 (FIG. 1f) is deposited by ALD method. The followed is the fabrication of a nanopore 6 with size of 10 nm (FIG. 1g, FIG. 6 and FIG. 7) through the stacked structure.

Results and analysis: In general, the first insulating layer 2 may include a material selected from the group consisting of SiO₂, BN, HfO₂, Al₂O₃, SiNxSiC, PVA, poly(4-vinylphenol), divinyltetramethyldisiloxane-bis-benzocyclobutene, and PMMA. In this embodiment, polymer insulator, PVA is selected as the first insulating layer 2.

The material for symmetrical electrode array can be selected from the group of layered conductive material, including graphite, graphene layer, reduced graphene oxide, partially hydrogenated graphene, BNC, MoS₂, NbSe₂, and Bi₂Sr₂CaCu₂Oₓ. In the present embodiment, graphene is adopted for fabrication of the symmetrical electrode array.

Different preparation methods may be employed to prepare graphene films, such as CVD, surface segregation, and mechanical exfoliation. In this embodiment, HOPG is used as the solid carbon source to synthesize single-layer graphene with high homogeneity on Ni catalytic layer.

In this embodiment, the thickness of the graphene electrode layer 7 is 0.335 nm, and the symmetrical electrode array 3 has 4-paired electrodes.

To pattern the electrode layer 7 into a symmetrical electrode array 3 can be carried out by various techniques as known in the art, including photolithography, electron beam lithography, laser photolithography, reactive ion-beam etching, oxygen plasma etching, and helium plasma etching. In this embodiment, helium ion-beam technique is adopted to fabricate the symmetrical electrode array 3.

The electrical contact layer 4 coupled to the symmetrical electrode array 3 can be selected from the group consisting of Au, Cr, Ti, Pd, Pt, Cu, Al, Ni, and PEDOT:PSS. The preparation of an electrical contact layer 4 can be done by the methods as known in the art such as vacuum thermal evaporation, solution-based spin-coating, thermal oxidation, low pressure CVD, plasma enhanced chemical vapor deposition (PECVD), and ALD methods. The thickness of an electrical contact layer is 15-600 nm, and preferably 20-50 nm. In this embodiment, a stacked Cr (5 nm)/Au (50 nm) layer is used as the electrical contact layer 4, which is prepared by photolithography and lift-off techniques. In this embodiment, a layer consisting of Ti (10 nm)/Au (50 nm) is used as the electrical contact layer 4, electrically coupled to the symmetrical electrode array 3.

The materials used as the second insulating layer 5 may be selected from the group of inorganic insulators including SiO₂, Al₂O₃, BN, SiC, SiNₓ, and HfO₂, and organic insulators including PVA, poly(4-vinylphenol), divinyltetramethyldisiloxane bis-benzocyclobutene, and PMMA. The second insulating layer 5 with typical thickness of 3 nm-3 μm can be prepared by the methods as known in the art, including but not limited to vacuum thermal evaporation, solution-based spin-coating, thermal oxidation, low pressure CVD, PECVD, and ALD methods. In this embodiment, ALD method is adopted to prepare 100 nm SiNₓ as the second insulating layer 5.

There are many nanofabrication techniques that may be used to fabricate a nanopore 6 through the stacked layers. Those nanofabrication techniques may include electron beam lithography, focused ion-beam etching, pulsed ion-beam etching, and helium ion-beam etching. The size or diameter a nanopore with various shapes is 1-50 nm. In this embodiment, the diameter of the nanopore 6 is 10 nm.

In this embodiment, the electrode layer of nanopore electrical sensor is made by transferring the graphene layer onto a polymer insulating layer. And helium ion-beam etching technology is used to fabricate the symmetrical electrode array.

Although the invention has been shown and described with respect to one or more implementations, equivalent alterations and modifications will occur to others skilled in the art base upon a reading and understanding of this specification and the exemplary embodiments. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and advantageous for any given or particular application.

1. A nanopore electrical sensor comprises a layered structure comprising a substrate (1), a first insulating layer (2), a symmetrical electrode array (3) and a second insulating layer (5) from bottom to top with a nanopore (6) provided in the center of the substrate (1), the first insulating layer (2), the symmetrical electrode array (3) and the second insulating layer (5).

2. The nanopore electrical sensor according to claim 1, wherein the upper surface of the first insulating layer (2) and edge of the symmetrical electrode array (3) are connected to a separate electrical contact layer (4), and each electrical contact layer (4) is electrical coupled to each electrode in the symmetrical electrode array (3).

3. The nanopore electrical sensor according to claim 1, wherein said symmetrical electrode array (3) comprises 1-30 pairs of separate nanoelectrodes with thickness of 0.3-3.5 nm, symmetrically distributed around and connected with a nanopore (6).

4. The nanopore electrical sensor according to claim 3, wherein said symmetrical electrode array comprises 1-10 pairs of separate nanoelectrodes and the thickness of the nanoelectrode is of 0.3-1 nm.

5. The nanopore electrical sensor according to claim 1 or 2 or 3 or 4, wherein a material for said symmetrical electrode array (3) is layered conductive materials, said layered conductive materials include graphite, reduced graphene oxide, partially hydrogenated graphene, BNC, MoS₂, NbSe₂ and Bi₂Sr₂CaCu₂Oₓ.

6. The nanopore electrical sensor according to claim 5, wherein said layered conductive material is the graphite, specifically the graphite films with 1-10 graphene layers.

7. The nanopore electrical sensor according to claim 6, wherein the number of layers of said graphene films is 1-3.

8. The nanopore electrical sensor according to claim 5, wherein said layered conductive material is reduced graphene oxide films with 1-10 layers, specifically conductive reduced graphene oxide membrane obtained by carrying out reduction reaction of graphene oxide films.

9. The nanopore electrical sensor according to claim 8, wherein the number of layers of said reduced graphene oxide membrane is 1-3.

10. The nanopore electrical sensor according to claim 5, wherein said layered conductive material is the partially hydrogenated graphene with 1-10 layers, specifically the hydrogenated graphene membrane obtained after the graphene membrane reacts with hydrogen and part of sp² keys of the graphene are converted to C—H sp³ keys.

11. The nanopore electrical sensor according to claim 10, wherein the number of layers of said partially hydrogenated graphene is 1-3.

12. The nanopore electrical sensor according to claim 5, wherein said layered conductive material is the BNC, specifically the BNC membrane with 1-10 layers.

13. The nanopore electrical sensor according to claim 12, wherein the number of layers of said BNC membrane is 1-3.

14. The nanopore electrical sensor according to claim 5, wherein said layered conductive material is the MoS₂, specifically the MoS₂ membrane with 1-10 layers.

15. The nanopore electrical sensor according to claim 14, wherein the number of layers of said MoS₂ membrane is 1-3.

16. The nanopore electrical sensor according to claim 5, wherein said layered conductive material is the NbSe₂, specifically the NbSe₂ membrane with 1-10 layers.

17. The nanopore electrical sensor according to claim 16, wherein the number of layers of said NbSe₂ membrane is 1-3.

18. The nanopore electrical sensor according to claim 5, wherein said layered conductive material is the Bi₂Sr₂CaCu₂Oₓ, specifically the Bi₂Sr₂CaCu₂Oₓ membrane with 1-10 layers.

19. The nanopore electrical sensor according to claim 18, wherein the number of layers of said Bi₂Sr₂CaCu₂Oₓ membrane is 1-3.

20. The nanopore electrical sensor according to claim 1 or 2 or 3 or 4, wherein a material of said substrate (1) is selected from the group of semiconductive material including one or mixture of Si, GaN, Ge and GaAs, and of insulating material including one or mixture of SiC, Al₂O₃, SiNₓ, SiO₂, HfO₂, PVA, Poly(4-vinylphenol), Divinyltetramethyldisiloxane bis-benzocyclobutene and PMMA.

21. The nanopore electrical sensor according to claim 1 or 2 or 3 or 4, wherein a material of said the first insulating layer (2) and the second insulating layer (5) includes one or mixture of SiC, Al₂O₃, SiNₓ, SiO₂, HfO₂, PVA, Poly(4-vinylphenol), Divinyltetramethyldisiloxane-bis-benzocyclobutene or PMMA.

22. The nanopore electrical sensor according to claim 1 or 2 or 3 or 4, wherein said second insulating layer (5) completely cover said symmetrical electrode array (3).

23. The nanopore electrical sensor according to claim 1 or 2 or 3 or 4, wherein said nanopore (6) is a round hole with diameter of 1-50 nm.

24. The nanopore electrical sensor according to claim 23, wherein the diameter of said nanopore (6) is 1-10 nm.

25. The nanopore electrical sensor according to claim 24, wherein the diameter of said nanopore (6) is 1-3 nm.

26. The nanopore electrical sensor according to claim 1 or 2 or 3 or 4, wherein said nanopore (6) is a polygon hole or an elliptical hole.

27. The nanopore electrical sensor according to claim 2, wherein said a material of electrical contact layer (4) includes Au, Cr, Ti, Pd, Pt, Cu, Al, Ni or PSS: one (or more) mixture of PEDOT.
